(19) United States
(12) Patent Application Publication
(10) Pub. No.: US 2005/0082950 A1
(43) Pub. Date: Apr. 21, 2005

(54) Piezoelectric actuator module, motor module and apparatus

(75) Inventor: Makoto Zakoji, Shiojiri-shi (JP)

Correspondence Address: SHINJYU GLOBAL IP COUNSELORS, LLP, 1233 20TH STREET, NW, SUITE 700, WASHINGTON, DC, 20036-2680, US

(73) Assignee: Seiko Epson Corporation, Shinjyuku-ku (JP)

(21) Appl. No.: 10/916,639

(22) Filed: Aug. 12, 2004

(30) Foreign Application Priority Data
Aug. 13, 2003 (JP) 2003-293202

(51) Int. Cl. H01L 41/053

(52) U.S. Cl. 310/348

(57) ABSTRACT

To provide a highly versatile piezoelectric actuator module that can be made thinner and is easy to handle.

A piezoelectric actuator module I0 includes a piezoelectric actuator main body 21 having electrodes, a plurality of signal input terminals 18A to 18D whereby a drive signal is inputted from the exterior and supplied to the electrodes, a rotating body 22 that is disposed in substantially the same plane as the piezoelectric actuator main body 21 and is driven and rotatably moved by the piezoelectric actuator main body 21, a casing 15 for accommodating the piezoelectric actuator main body electrically connected to the rotating body 22 and the signal input terminals, and an output shaft 12 which is exposed from the casing 15 and by which the rotational movement transmitted directly or indirectly by the rotating body 22 is outputted to the exterior.

### FIELD OF THE INVENTION

The present invention relates to a piezoelectric actuator module, an electric motor module, and an apparatus using the same.

### DESCRIPTION OF THE RELATED ART

Piezoelectric actuators based on the use of piezoelectric elements are known in conventional practice (for example, see Japanese Patent No. 3241688).

### SUMMARY OF THE INVENTION

Problems the Invention is Intended to Solve

However, when piezoelectric actuators are configured in the manner described in the above-mentioned Japanese Patent No. 3241688, problems arise in the sense that the actuators themselves are thick and that it is difficult to reduce the thickness of the apparatus containing these piezoelectric actuators. In view of this, an object of the present invention is to provide a highly versatile, thin, and easy-to-handle piezoelectric actuator module, electric motor module, and apparatus equipped with the piezoelectric actuator module and the electric motor module.

Means for Solving the Problems

In order to solve the problems described above, a piezoelectric actuator module is provided having a piezoelectric actuator main body with electrodes, a signal input terminal to input a drive signal from the exterior and to supply the drive signal to the electrodes, a rotating body that is disposed in substantially the same plane as the piezoelectric actuator main body in contact with part of the piezoelectric actuator main body and is rotatably driven by the piezoelectric actuator main body, a casing to accommodate the piezoelectric actuator main body electrically connected to the rotating body and the signal input terminal, and an output shaft which is exposed from the casing and by which the rotational movement transmitted directly or indirectly by the rotating body is outputted to the exterior.

In this case, a slider to support the piezoelectric actuator main body is included, wherein the piezoelectric actuator main body may be pressed against the rotating body by rotating or translating the slider. Also, an urging member to urge the slider toward the rotating body may be included. Furthermore, the urging member may be configured to be replaceable. Furthermore, an urging force varying part to vary the urging force applied to the slider by the urging member may be included.

Also, the casing may include a lid unit and a casing main body, wherein the lid includes a first lid unit to cover the portions corresponding to the rotating body and the output shaft, and a second lid unit to cover the portion corresponding to the piezoelectric actuator main body. Furthermore, the first lid unit and the second lid unit may be designed to be able to be assembled in a partially overlapped state. Furthermore, an observation window or transparent member than allows the state of contact to be observed from the exterior of the casing may be provided to the casing.

Also, the rotating body may have an axle, and a bearing part to support the axle may be extended from the peripheral surface of the casing. Furthermore, the output shaft may be connected to the axle, and a drive force transmission part may be connected via the output shaft. Furthermore, the drive force transmission part may have a gear or a cam, and the gear or cam may be either fixed or detachably disposed.

Also, the output shaft may have a substantially cylindrical shape. Furthermore, the ground electric potential of the driving power source of the piezoelectric actuator main body may be the same as the electric potential of the casing. Furthermore, the piezoelectric actuator module may be designed such that the piezoelectric actuator main body includes a substrate in which piezoelectric elements are layered over a plurality of regions on the surface thereof, a fixing part to fix the substrate to the slider, and a contact portion provided to the longitudinal end of the substrate, and the piezoelectric elements are stretched and contracted by supplying a drive signal to the piezoelectric elements to create longitudinal oscillation whereby the oscillating plate expands and contracts in the longitudinal direction, and to create curved oscillation in a direction intersecting with the longitudinal direction, and the rotating body is rotatably driven by the displacement of the contact portion that accompanies a combined oscillation obtained by combining these oscillations.

In another arrangement, a supporting slider is provided to press the piezoelectric actuator main body against the rotating body, and a flexible substrate designed to supply driving electric power to the piezoelectric actuator main body from an external connecting terminal and electrically connected to the electrodes of the piezoelectric actuator main body, wherein the flexible substrate includes a casing support part supported by the casing, a slider support part supported by the slider, and a damper part disposed in the middle portion between the casing support part and the slider support part and designed to reduce stress or to suppress oscillation transmission between the two support parts. In yet another arrangement, the piezoelectric actuator main body includes a substrate in which piezoelectric elements are layered on the surface thereof, and a contact portion that is configured separately from the substrate supported by the substrate, and pressed against the rotating body; and at least the portion of the contact portion pressed against the rotating body is configured with a higher degree of hardness than that of the substrate. In still another arrangement, one end of the contact portion protrudes from the end surface of the substrate in a specific direction, and the other end is fixed in place and supported in a concavity provided to one end of the substrate. Also, the contact portion may be configured from ceramics, cemented carbide, nitrided steel, or cemented steel. Also, a plurality of electrodes and signal input terminals may be provided.

Also, provided is an electric motor module having a piezoelectric actuator main body with electrodes, a plurality of signal input terminals to input a drive signal and to supply the drive signal to the electrodes, a rotating body that is disposed in substantially the same plane as the piezoelectric actuator main body in contact with part of the piezoelectric actuator main body and that is driven and rotatably moved by the piezoelectric actuator main body, a casing to accommodate the piezoelectric actuator main body electrically connected to the rotating body and the signal input terminals, an output shaft which is exposed from the casing and by which the rotational movement transmitted directly or indirectly by the rotating body is outputted to the exterior, and a drive circuit that creates a drive signal on the basis of the electric power supplied from the exterior and outputs the signal to the signal input terminal.

Also provided is an apparatus having a piezoelectric actuator main body with electrodes, a plurality of signal input terminals to input a drive signal and to supply the drive signal to the electrodes, a rotating body that is disposed in substantially the same plane as the piezoelectric actuator main body in contact with part of the piezoelectric actuator main body and that is driven and rotatably moved by the piezoelectric actuator main body, a casing to accommodate the piezoelectric actuator main body electrically connected to the rotating body and the signal input terminals, an output shaft which is exposed from the casing and by which the rotational movement transmitted directly or indirectly by the rotating body is outputted to the exterior, a driven part that is connected to and driven by the output shaft, a power source to supply electric power, and a drive circuit to create a drive signal on the basis of the electric power supplied from the power source and outputting the signal to the signal input terminals. In this case, the driven body may be a gear, a propeller, or a tool attachment.

Effects of the Invention

According to the present invention, it is possible to configure a highly versatile piezoelectric actuator module that is easy to handle and that can be made thinner, and a device in which the piezoelectric actuator module is installed can therefore be made thinner and more compact.

### BRIEF DESCRIPTION OF THE DRAWINGS

FIG. 1 is an external perspective view of a piezoelectric actuator module of a first embodiment;

FIG. 2 is a top view of the piezoelectric actuator module of the first embodiment;

FIG. 3 is a top view of the piezoelectric actuator main body (oscillator);

FIG. 4 is a side view of the piezoelectric actuator main body (oscillator);

FIG. 5 is a top perspective view of the piezoelectric actuator main body not yet fixed to a slider;

FIG. 6 is a top perspective view of the piezoelectric actuator main body that has been fixed to a slider;

FIG. 7 is a bottom perspective view of the piezoelectric actuator main body already fixed to a slider;

FIG. 8 is an external perspective view of the slider and piezoelectric actuator main body of FIG. 7 incorporated in a casing main body;

FIG. 9 is an external perspective view of a flexible substrate;

FIG. 10 is a top view of the flexible substrate;

FIG. 11 is a side view of the flexible substrate;

FIG. 12 is a front view of the flexible substrate;

FIG. 13 is a connection diagram of the flexible substrate;

FIG. 14 is a top view of the piezoelectric actuator module of a first modification;

FIG. 15 is a top view of the piezoelectric actuator module of a third modification;

FIG. 16 is a side view of the piezoelectric actuator module of the third modification;

FIG. 17 is a front view of the piezoelectric actuator module of the third modification;

FIG. 18 is a top view of the slider of a fifth modification;

FIG. 19 is an external perspective view of the slider and piezoelectric actuator main body in FIG. 18 incorporated into a casing main body;

FIG. 20 is a top view of a piezoelectric actuator of a second embodiment;

FIG. 21 is a top view of a piezoelectric actuator module of a third embodiment;

FIG. 22 is a side view of the piezoelectric actuator module of the third embodiment;

FIG. 23 is a front view of the piezoelectric actuator module of the third embodiment;

FIG. 24 is a side view taken along a cross section A-A of the piezoelectric actuator module 10Y;

FIG. 25 is a diagram for describing a modification of the third embodiment;

FIG. 26 is a top view of a piezoelectric actuator module of a fourth embodiment;

FIG. 27 is a side cross-sectional view of the piezoelectric actuator module of the fourth embodiment;

FIG. 28 is a front cross-sectional view of the piezoelectric actuator module of the fourth embodiment;

FIG. 29 is an external perspective view of the piezoelectric actuator module of the fourth embodiment;

FIG. 30 is an external perspective view of a piezoelectric actuator module of a fifth embodiment;

FIG. 31 is a side view taken along a cross section A-A of the piezoelectric actuator module of the fifth embodiment;

FIG. 32 is a diagram (part 1) for describing a more specific example of applying the fifth embodiment;

FIG. 33 is a diagram (part 2) for describing a more specific example of applying the fifth embodiment;

FIG. 34 is a main part of the embodiment of a sixth embodiment;

FIG. 35 is an external perspective view of the actuator module applied to a model airplane (aircraft);

FIG. 36 is a partial cross-sectional view of a propeller device;

FIG. 37 is an external perspective view of an electrical tool of an eighth embodiment;

FIG. 38 is a schematic structural block diagram of an electrical tool of the eighth embodiment;

FIG. 39 is a schematic structural block diagram of an electric motor module of a ninth embodiment;

FIG. 40 is an external perspective front view of an oscillating electric motor module of the tenth embodiment;

FIG. 41 is an explanatory diagram of a state in which the oscillating electric motor module is incorporated into a portable phone;

FIG. 42 is a top view of the piezoelectric actuator main body (oscillator) of an eleventh embodiment;

FIG. 43 is a top view of a piezoelectric actuator main body (oscillator) of a twelfth embodiment;

FIG. 44 is an external perspective view of the contact portion;

FIG. 45 is a side view of the piezoelectric actuator main body (oscillator) of the twelfth embodiment;

FIG. 46 is a top view of a piezoelectric actuator main body (oscillator) of a thirteenth embodiment; and

FIG. 47 is a side view of the piezoelectric actuator main body (oscillator) of the thirteenth embodiment.

### DESCRIPTION OF THE PREFERRED EMBODIMENTS

The embodiments of the present invention will now be described with reference to the diagrams.

### [1] First Embodiment

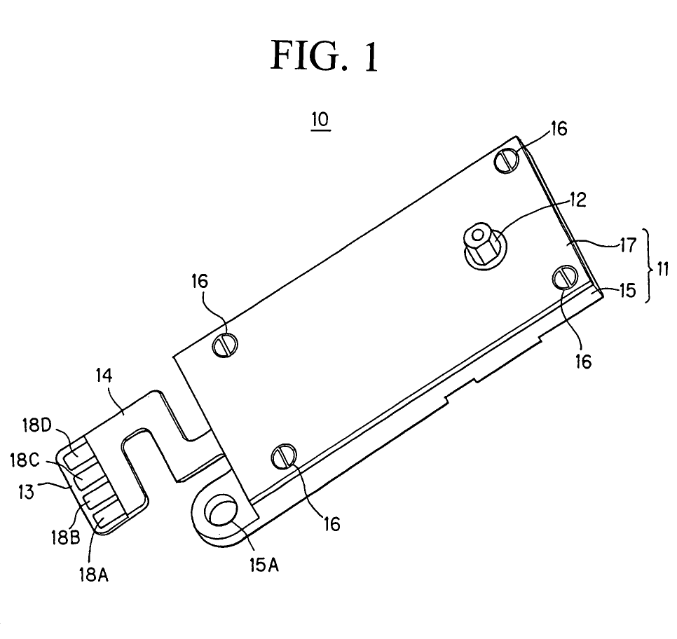

The first embodiment will be described first. FIG. 1 is an external perspective view of a piezoelectric actuator module of the first embodiment. A piezoelectric actuator module 10 includes a casing (case unit) 11 and an output shaft 12 to transmit drive force that is extended and exposed from the topside of the casing 11. Furthermore, a flexible substrate 14 provided with an external connection terminal 13 extends from one end of the casing 11 in the longitudinal direction.

The casing 11 includes a casing main body 15, and a lid unit 17 fixed to the casing main body 15 by screws 16. The lid unit protects the piezoelectric actuator main body described hereinafter in conjunction with the casing main body 15. The size of the casing 11 is such that, for example, the length in the transverse direction of the lid unit 17 is approximately 6 mm, and the length in the longitudinal direction is approximately 13 mm. Also, the casing main body 15 is provided with a fixing screw hole 15A to fix the piezoelectric actuator module 10 to the device on which it is to be mounted. Furthermore, the external connection terminal 13 is provided with electrodes 18A to 18D that are electrically connected to the piezoelectric actuator main body via a connecting wire described hereinafter.

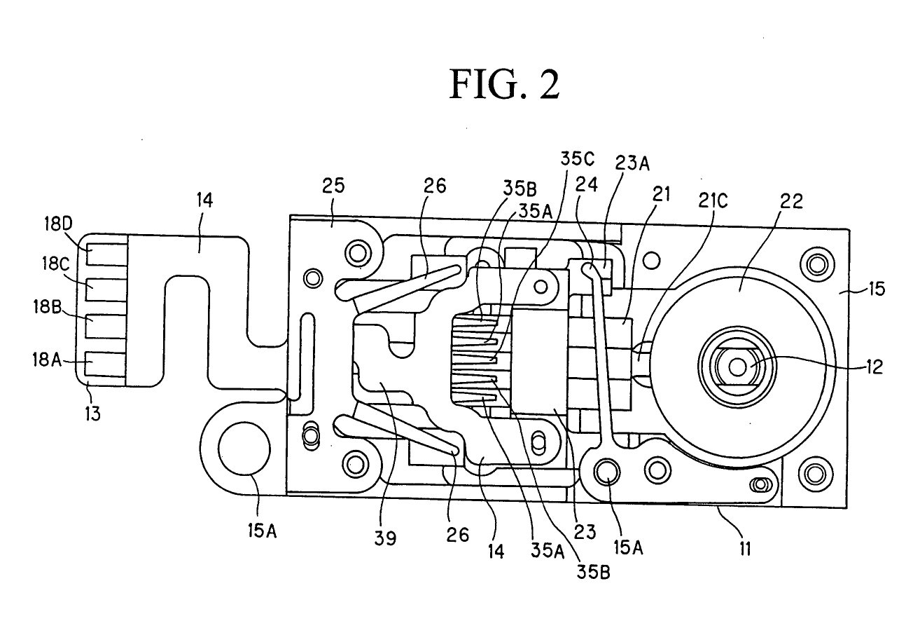

FIG. 2 is a top view of the piezoelectric actuator module of the first embodiment. A piezoelectric actuator main body 21 is provided inside the casing main body 15. The piezoelectric actuator main body 21 is supported by a slider 23. Also, the interior of the casing main body 15 is provided with a rotating body 22 that functions as a driven member driven by the piezoelectric actuator main body 21 and provided with the output shaft 12 exposed from the casing main body 15. The slider 23 supports the piezoelectric actuator main body 21 at an oscillation node of the piezoelectric actuator main body 21, or, specifically, at a position where the displacement during oscillation is virtually zero.

The slider 23 is intended to maintain the supported piezoelectric actuator main body 21 in contact with the rotating body 22, and is urged toward the rotating body 22 by an urging member 24 interlocked with an interlocking protrusion 23A of the slider 23. The urging member 24 is disposed at a position overlapping the piezoelectric actuator main body 21 in the thickness direction (the direction perpendicular to the paper surface of FIG. 2), allowing for a more compact design. Furthermore, the urging member 24 has an easily replaceable structure, and the drive torque of the rotating body 22, and hence of the output shaft 12, can be varied by replacing the urging member 24 with one having a different urging force. Furthermore, since a configuration is employed wherein the slider 23 is rotated about an axle 15A to maintain the piezoelectric actuator main body 21 in contact with the rotating body 22, a stable urging force (pressure) can be applied with a single elastic member, and the resulting drive torque can be stabilized.

Also, the piezoelectric actuator main body 21 and the rotating body 22 are disposed such that the centerline in the longitudinal direction passes through the center of rotation of the rotating body 22 when the piezoelectric actuator main body 21 has a substantially rectangular shape. This arrangement is adopted in order to reduce the mounting space and to ensure that the drive force of the piezoelectric actuator main body 21 is set to be substantially equal during direct and reverse rotations of the rotating body 22. Also, the piezoelectric actuator main body 21 is disposed nearly in the middle in the longitudinal direction of the casing main body 15, and the mounting surface area can be reduced. A fixing member 25 fixes the flexible substrate 14 to the casing main body 15 on the side of the external connection terminal 13. The fixing member 25 has a shock preventing spring 26, and the shock preventing spring 26 urges the slider 23 from the topside of the slider 23 (the side with the lid unit 17) toward the bottom (the side with the casing main body 15) to prevent shock in the slider 23. As a result, it is possible to ensure reliably conduction between the piezoelectric actuator main body 21 and the electrodes (overhanging electrodes described hereinafter) of the flexible substrate 14.

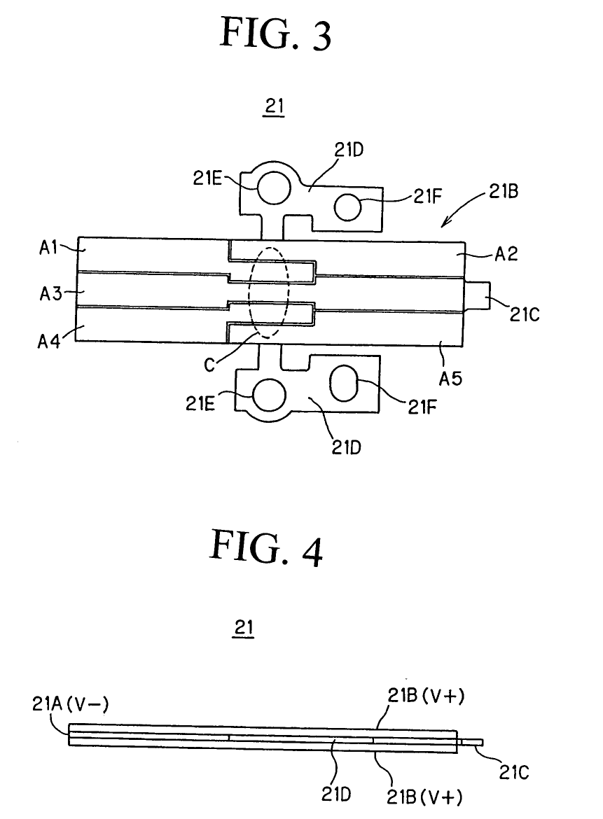

The components constituting the piezoelectric actuator module will now be described in detail. First, the piezoelectric actuator main body will be described. FIG. 3 is a top view of the piezoelectric actuator main body (oscillator). FIG. 4 is a side view of the piezoelectric actuator main body (oscillator). The piezoelectric actuator main body 21 has a structure wherein PZT or other such piezoelectric elements 21B are affixed to both sides of a substrate (shim) 21A, which is an elastic member. In this structure, during actual driving, for example, a voltage V− (negative voltage) is applied to the substrate 21A, and a voltage V+ (positive voltage) is applied to the piezoelectric elements 21B.

Fixing units 21D to fix the piezoelectric actuator main body 21 to the slider 23 are provided to both sides of the substrate 21 A, and the main body is supported with the sections to which the piezoelectric elements 21B are affixed in a suspended state. These fixing units 21D are each provided with a positioning hole 21F and a screw hole 21E through which a screw is inserted for fixing the main body to the slider 23. The piezoelectric elements 21B are provided with five regions A1 to A5 per side, and the regions A1 and A5 are used as a pair. The regions A2 and A4 are similarly used as a pair. Specifically, the same drive signal is applied to the regions used as pairs.

More specifically, for example, the piezoelectric actuator main body 21 is driven by applying separate drive signals to the regions A1 and A5 and to the regions A2 and A4. Initiating longitudinal oscillation in the regions A1 and A5, causing the regions A2 and A4 to oscillate, and not oscillating the region A3 creates an imbalance in stretching and contraction in the longitudinal direction, induces curved oscillation, and creates oscillation along an elliptical orbit in a constant direction in relation to a contact portion 21C hereinafter described (for example, in a clockwise direction). At this point, the electrode corresponding to the region A3 serves as a detection electrode. Furthermore, a region C in the middle of the substrate 21A in the longitudinal direction is equivalent to a so-called node that is not affected by the oscillation of the piezoelectric actuator, and this region is used an electrode connector. Also, the electrodes are disposed in a single row in this region C, which results in an easily mountable structure.

One end of the piezoelectric actuator main body 21 in the longitudinal direction of the substrate 21A is provided with the contact portion 21C pressed against the rotating body 22 to transmit the drive force. A drive voltage is applied to the piezoelectric elements 21B via the region C, whereby a longitudinal oscillation of expansion and contraction in the longitudinal direction and a curved oscillation in a rough S shape are created in the piezoelectric actuator main body 21, and the rotating body 22 is driven while these oscillations combine together and cause the tip of the contact portion 21C to describe an elliptical trajectory. As a result, the rotating body 22 performs rotational movement.

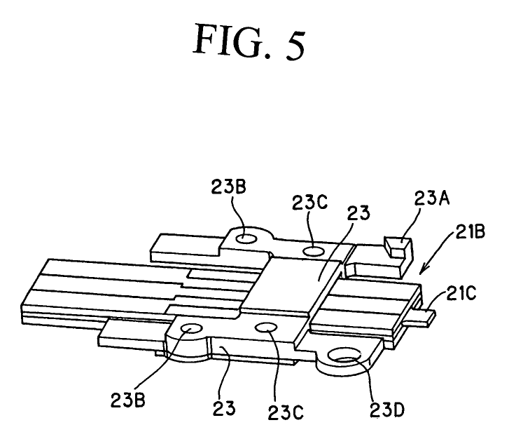

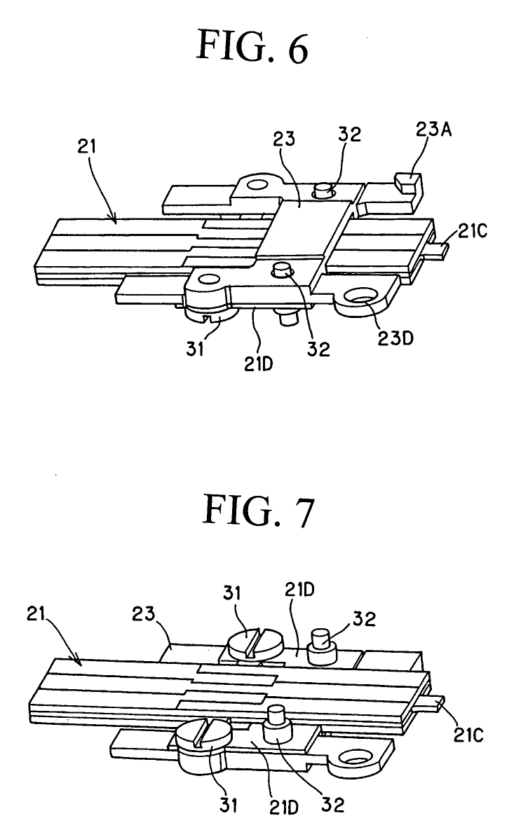

Next, the slider will be described. FIG. 5 is a top perspective view of the piezoelectric actuator main body not yet fixed to the slider. FIG. 6 is a top perspective view of the piezoelectric actuator main body already fixed to the slider. FIG. 7 is a bottom perspective view of the piezoelectric actuator main body already fixed to the slider. The slider 23 has a profile with a rough H shape in a plan view, and includes an interlocking protrusion 23A hereinafter described, screw insertion holes 23B through which are inserted screws 31 to fix the piezoelectric actuator main body 21, pin insertion holes 23C through which are inserted interlocking pins 32 to interlock with the flexible substrate 14, and an axle insertion hole 23D through which is inserted the axle 15A (see FIG. 2) provided to the casing main body 15 and used as the center of rotation under urging by the urging member 24.

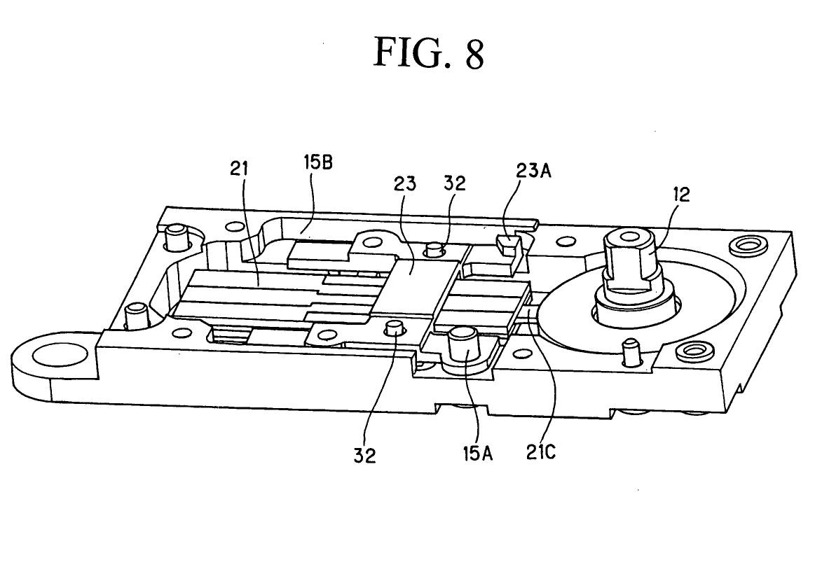

FIG. 8 is an external perspective view of the slider and piezoelectric actuator main body in FIG. 7 incorporated in a casing main body. The flexible substrate is not shown in FIG.8 for the sake of simplicity. The slider 23 and the piezoelectric actuator main body 21 are placed along with the rotating body 22 in a holding concavity 15B in the casing main body 15 in a fixed state. At this time, the contact portion 21C is disposed to be able to be easily pressed against the peripheral surface of the rotating body 22 by rotation about the axle 15A.

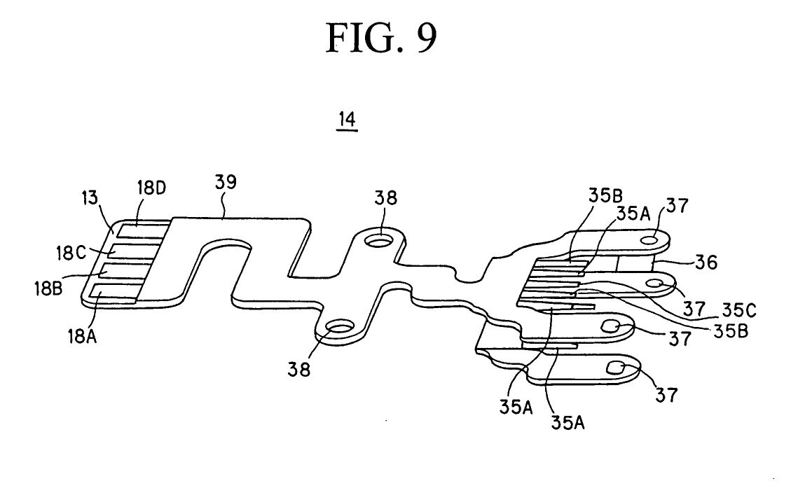

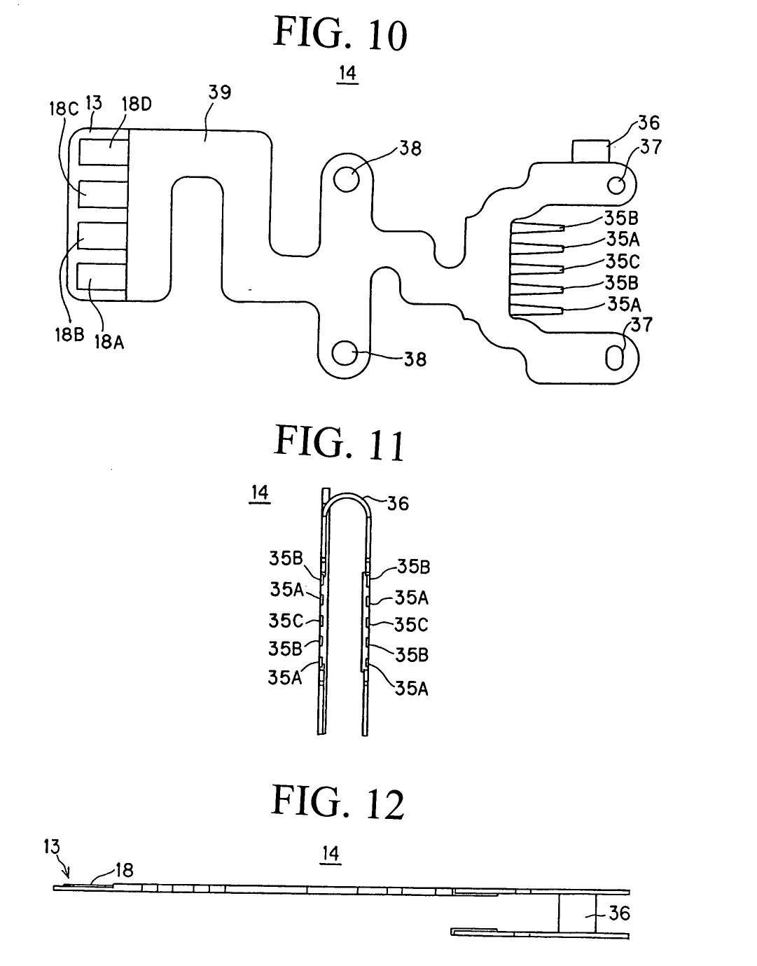

FIG. 9 is an external perspective view of the flexible substrate. FIG. 10 is a top view of the flexible substrate. FIG. 11 is a side view of the flexible substrate. FIG. 12 is a front view of the flexible substrate. The flexible substrate 14 is provided with ten overhanging electrodes 35 as shown in the external perspective view in FIG. 8 and the side view in FIG. 10 (in FIG. 2, only five are visible).

These overhanging electrodes 35 are soldered to the electrodes of the piezoelectric actuator main body 21, are electrically connected by deposition or the like while fixed in place, and are used to supply a drive force. More specifically, the overhanging electrodes 35 are classified into three systems: electrodes 35A, electrodes 35B, and electrodes 35C. In this case, the electrodes 35A are configured to supply the same drive signal to the pair of regions A1 and A5 from among the regions Al to A5 of the piezoelectric elements 21B shown in FIG. 3. Also, the electrodes 35B are similarly configured so as to supply the same drive signal to the regions A2 and A4 used as a pair. Furthermore, the electrodes 35C are configured to supply a drive signal to the region A3. Specifically, the flexible substrate 14 is configured as a multilayered substrate, and the overhanging electrodes 35 are electrically connected to their corresponding electrodes 18A to 18D by multilayered wiring.

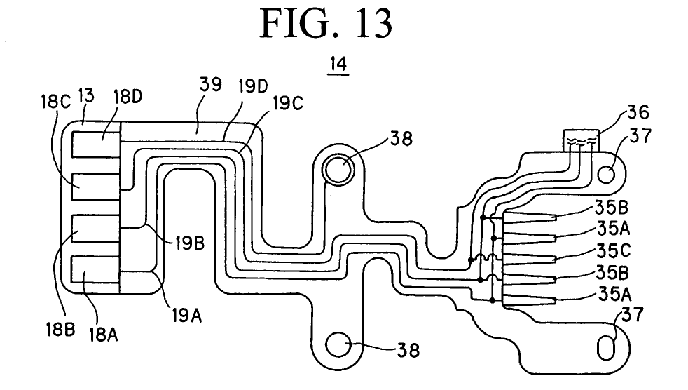

FIG. 13 is a connection diagram showing one example of wiring. The electrodes 35A are connected to the electrode 18A of the external connection terminal 13 via a connecting wire 19A, as shown in FIG. 13. Also, the electrodes 35B are connected to the 18B of the external connection terminal 13 via a connecting wire 19B. Furthermore, the electrodes 35C are connected to the electrode 18C of the external connection terminal 13 via a connecting wire 19C. Additionally, the electrode 18D is electrically connected to the substrate 21 A of the piezoelectric actuator main body 21 via a positioning hole 38 hereinafter described.

Loss during oscillation (during driving) of the piezoelectric actuator main body 21 can be reduced because the electrodes 35A to 35C constituting the overhanging electrodes 35 are composed solely from a pattern of conductive material (copper or the like), and not from the base material that constitutes the flexible substrate 14. Furthermore, the electrodes 35A to 35C constituting the overhanging electrodes 35 are made thinner towards the distal end (the side with the connecting parts of the piezoelectric actuator main body). Thus, the flexural stress generated along with the oscillation of the piezoelectric actuator main body 21 is reduced, and the oscillation loss (energy loss) through the overhanging electrodes during oscillation of the piezoelectric actuator main body 21 is reduced to allow for highly efficient driving.

In this case the distal end section of the flexible substrate 14 containing the overhanging electrodes 35 is curved into a rough U shape by a linking part 36 to allow the piezoelectric actuator main body 21 to be held therebetween, as shown in the side view. Thus, a configuration is provided wherein one flexible substrate 14 is bent into a rough U shape and electric power is supplied to both sides of the piezoelectric actuator main body 21, making it possible to reduce the number of components and to bring down the cost and size of the device.

Also, the five overhanging electrodes 35 that face the topside of the piezoelectric actuator main body 21 are bent towards the topside of the piezoelectric actuator main body 21 and are connected to the electrodes on the topside of the piezoelectric actuator main body 21. The other five overhanging electrodes 35 that face the bottom side of the piezoelectric actuator main body 21 are connected to the electrodes on the bottom side of the piezoelectric actuator main body 21. Thus, mounting is possible with one flexible substrate 14 on both sides of the piezoelectric actuator main body 21, resulting in a smaller number of components and improved handling.

Furthermore, positioning holes 37 to position the device in relation to the slider are provided to the distal end portion of the flexible substrate 14. Two positioning holes 37 are provided in the present embodiment, and one is a circular hole while the other is an oval hole. Furthermore, positioning holes 38 to position the device in relation to the fixing member 25 are provided to the middle portion of the flexible substrate 14.

Therefore, to connect electrically the flexible substrate 14 with the piezoelectric actuator main body 21, the positioning holes 38 are used to fix completely the flexible substrate 14 in place by fixing the flexible substrate 14 to the casing main body 15 on the side with the external connection terminal 13 by the fixing member 25. Also, the area between the external connection terminal 13 and the middle portion of the flexible substrate 14, specifically, the portion provided with the positioning holes 38, constitutes a damper portion 39 with a damper function to absorb any stress than may be applied, and since the flexible substrate 14 is also fixed to the casing main body by the fixing member 25 with the use of the positioning holes 38, the drive force is not reduced because even when a tensile force is applied to the external connection terminal 13, the piezoelectric actuator main body 21 is not directly affected.

In this state (see FIG. 2), the shock preventing spring 26 of the fixing member 25 urges the slider 23 away from the topside of the slider 23 (the side with the lid unit 17) toward the bottom (the side with the casing main body 15), and the slider 23 can easily be prevented from undergoing shock even when the piezoelectric actuator main body 21 is in a state of oscillation.

The piezoelectric actuator module 10 is then completed as shown in FIG. 1 by fixing the lid unit 17 to the casing main body 15 with the screws 16. In the piezoelectric actuator module 10 with the configuration described above, a drive voltage is applied to the external connection terminal 13 from the exterior, whereby the piezoelectric actuator main body 21 having a structure in which the piezoelectric elements 21B is affixed to the substrate 21A oscillates in a state of being urged toward the rotating body 22 by the urging member 24 interlocked with the interlocking protrusion 23A of the slider 23. As a result, a longitudinal oscillation of expansion and contraction in the longitudinal direction, and a curved oscillation in a rough S shape combine together to drive the rotating body 22 and to rotate the rotating body 22t while the distal end of the contact portion 21C describes an elliptical trajectory.

At this time, the flexible substrate 14 is fixed to the slider 23, and can be very durable because no stress is generated in the overhanging electrodes 35 of the flexible substrate even when the piezoelectric actuator main body 21 and the slider 23 move. As a result, the rotational movement of the rotating body 22 drives the external driven member via the output shaft 12.

### [2] Modifications

Modifications of the first embodiment will now be described.

### [2.1] First Modification

In the above descriptions, to vary the drive torque of the output shaft 12, the urging member 24, which has an easily replaceable structure, was replaced with one having a different urging force, but the present first modification is one in which the drive torque of the output shaft 12 can be varied without replacing the urging member 24.

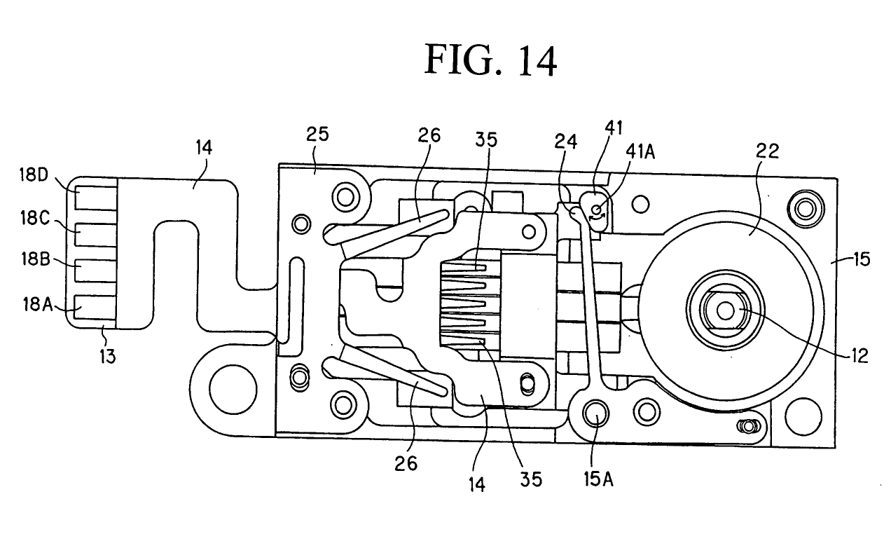

FIG. 14 is a top view of the piezoelectric actuator module of the first modification. In FIG. 14, the same components as in FIG. 2 are denoted by the same symbols. FIG. 2 is a top view of the piezoelectric actuator module of the first embodiment. The piezoelectric actuator main body 21 is provided on the inside of the casing main body 15. The piezoelectric actuator main body 21 is supported by the slider 23. The slider 23 is intended to maintain the supported piezoelectric actuator main body 21 in contact with the rotating body 22, and is urged toward the rotating body 22 by an urging member 24 interlocked with an urging force adjusting cam 41 rotatably fitted over an axle 41A provided to the slider 23. At this time, varying the urging force of the urging member 24 by rotating the urging force adjusting cam 41 makes it possible to easily vary the drive torque of the rotating body 22, and consequently of the output shaft 12 as well.

### [2.2] Second Modification

In the above descriptions, the electric potential level of the casing 11 was not described, but the piezoelectric actuator main body is brought to a shielded state and there is no need to take into account the effects of static electricity if the casing 11 is configured from metal or another such conductor and the electric potential level thereof is set at ground level. Furthermore, the grounding can be shared and the circuit configuration can be simplified.

### [2.3] Third Modification

In the above descriptions, the lid unit was integrated. However, when the lid unit is integrated, the rotating body and the piezoelectric actuator main body must both be assembled simultaneously and concurrently, and since the positioning relationship between the two is not fixed, adjustment and assembly are difficult as a result. In view of this, the third modification is one in which the lid unit is segmented and assembly can be improved.

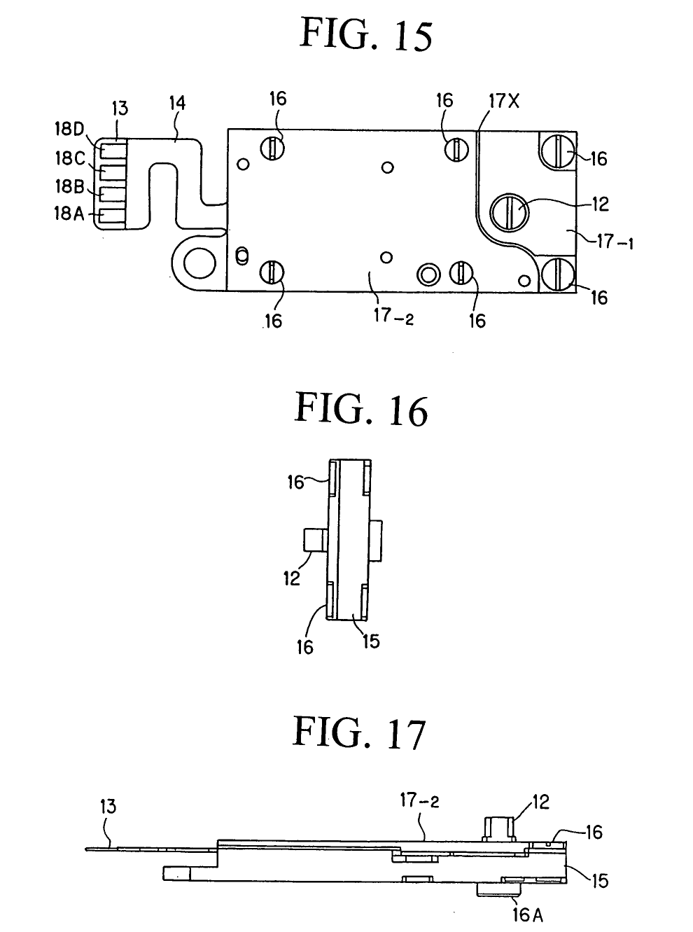

FIG. 15 is a top view of the piezoelectric actuator module of the third modification. FIG. 16 is a side view of the piezoelectric actuator module of the third modification. FIG. 17 is a bottom view of the piezoelectric actuator module of the third modification. In FIGS. 15 through 17, the same components as in FIG. 1 are denoted by the same symbols. In the third modification, the lid unit is configured from a first lid unit 17-1 fixed in place to cover the section that has the rotating body and the axle thereof, which is the output shaft 12, and also from a second lid unit 17-2 fixed in place to cover the piezoelectric actuator main body, part of the flexible substrate, and other sections thereof.

In this case, a seam portion 17X between the first lid unit 17-1 and second lid unit 17-2 is set such that the thickness of the lid units 17-1 and 17-2 is about half the other sections, which makes it possible to overlap the two components. As a result, it is possible to prevent debris or the like from penetrating into the completed piezoelectric actuator module from the exterior. As a result of employing such a configuration, any misalignment in the position of the rotating body is removed and assembly steps can be performed with greater ease if first the rotating body is incorporated into the casing main body 15, and the first lid unit 17-1 is fixed with the screws 16.

### [2.4] Fourth Modification

In the above descriptions, the bearing portion of the rotating body was not described in any detail, but it is preferable that a bearing part 16A protrude from the casing main body 15 as shown in FIG. 17 while the entire casing 11 (see FIG. 1) is made thinner in order to facilitate positioning and to prevent the output shaft 12 of the rotating body from tilting.

### [2.5] Fifth Modification

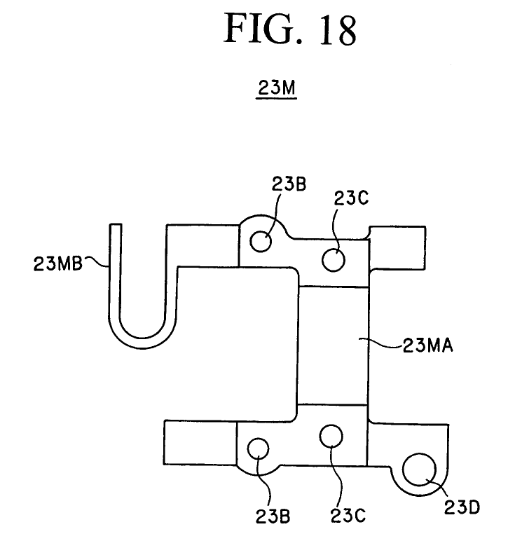

In the above descriptions, the piezoelectric actuator main body supported by the slider was pressed against the rotating body by the slider and another urging member, but the present modification is one in which the same effects may also be obtained by providing the urging member to the slider itself. FIG. 18 is a top view of the slider of the fifth modification. In FIG. 18, the same components as in FIG. 5 are denoted by the same symbols. A slider 23M is configured by integrating together a slider main body 23MA whose profile is a rough H shape in a plan view, and a roughly U shaped urging part 23MB on one end of the slider main body 23MA.

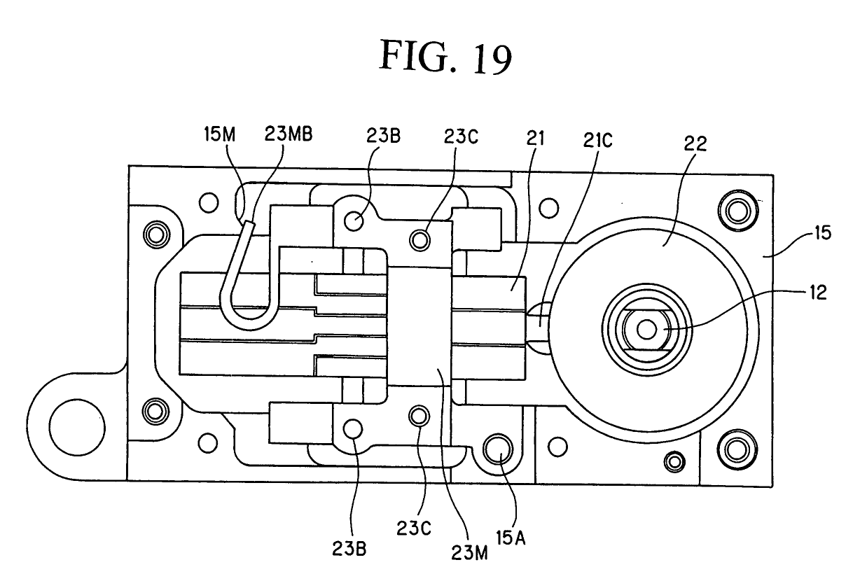

The slider main body 23MA includes a screw insertion hole 23B through which are inserted screws 31 to fix the piezoelectric actuator main body 21, pin insertion holes 23C through which are inserted interlocking pins 32 to interlock with the flexible substrate 14, and an axle insertion hole 23D through which is inserted an axle 15A (see FIG. 19) provided to the casing main body 15 and used as the center of rotation upon urging by the urging member 23MB.

FIG. 19 is an external perspective view of the slider and piezoelectric actuator main body in FIG. 18 incorporated in a casing main body. The flexible substrate is not shown in FIG. 19 for the sake of simplicity. The slider 23M and the piezoelectric actuator main body 21 are placed along with the rotating body 22 in a holding concavity 15B in the casing main body 15 in a fixed state. At this time, the urging part 23MB of the slider 23M interlocks with an interlocking protrusion 15M in the holding concavity 15B in an elastically deformed state, and the slider 23M is rotated about the axle 15A by the elastic force thereof, whereby the contact portion 21 C of the piezoelectric actuator main body 21 is pressed against the peripheral surface of the rotating body 22. Therefore, a stable urging force (pressure) is achieved with one elastic member, and the resulting drive torque is also stabilized in the fifth modification as well.

### [3] Second Embodiment

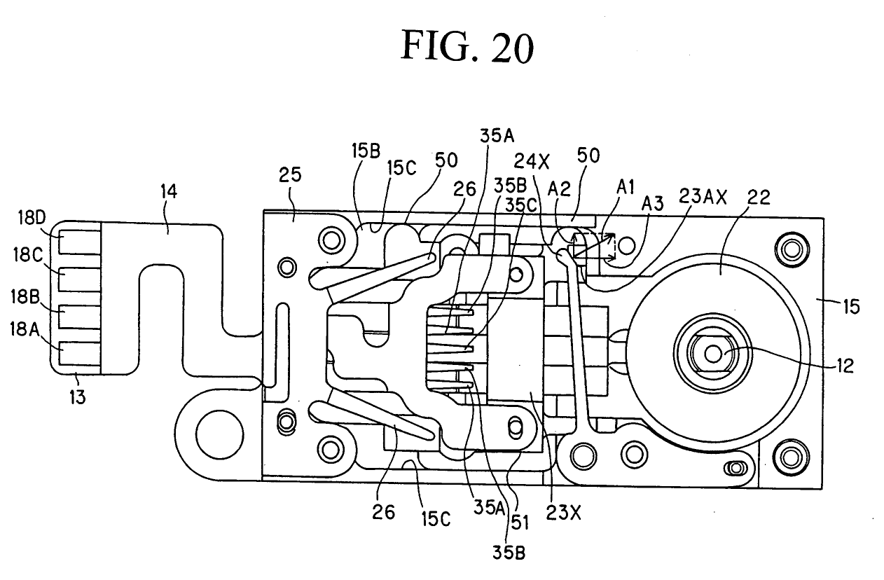

In the first embodiment described above, the contact portion of the piezoelectric actuator main body was pressed against the rotating body by rotating the slider about the axle, but the second embodiment is one in which the contact portion is pressed against the rotating body by sliding the slider toward the rotating body in translating motion. FIG. 20 is a top view of the piezoelectric actuator of the second embodiment. In FIG. 20, the same components as those in FIG. 2 are denoted by the same symbols. Either a side protuberance 50 or a side sliding part 51 of the slider 23X is slidably pressed against the sidewall 15C of the concavity 15B of the casing main body 15. Therefore, movement of the slider 23X only has a degree of freedom in the longitudinal direction of the piezoelectric actuator module.

In this state, the slider 23X is intended to maintain the supported piezoelectric actuator main body 21 in contact with the rotating body 22, and is urged toward the rotating body 22 by an urging member 24X interlocked with an interlocking protrusion 23AX of the slider 23X. If it is assumed at this time that the force vector provided to the interlocking protrusion 23AX by the urging member 24X is Al, then the resolved force vector in the transverse direction of the piezoelectric actuator module is A2, and the resolved force vector in the longitudinal direction is A3.

However, the resolved force vector A2 in the transverse direction is only manifested as friction force between the side protuberance 50 and the sidewall 15C. Specifically, the state of contact of the contact portion 21C of the piezoelectric actuator main body 21 with the rotating body 22 is substantially maintained due to the resolved force vector A3 in the longitudinal direction. Therefore, since the contact portion 21C is pressed against the rotating body 22 from the same direction, it is possible to drive the rotating body 22 in a more stable manner, and the resulting torque is more stable in comparison with the first embodiment.

### [4] Third Embodiment

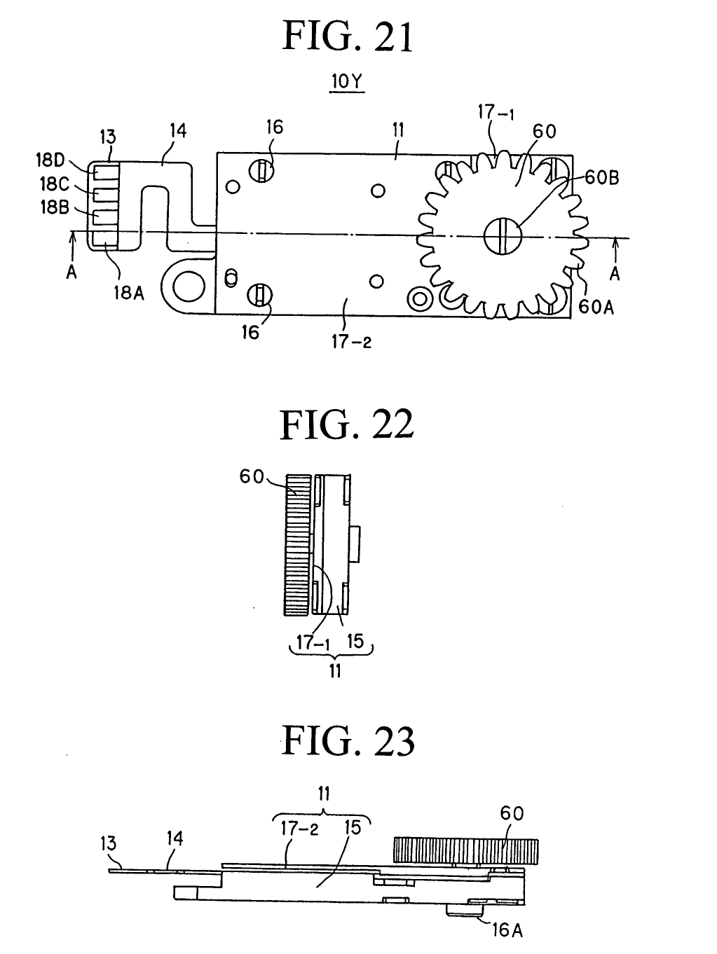

In the embodiments described above, the output shafts were different shafts, but the third embodiment is one in which a gear that functions as an output shaft is provided. [0049] FIG. 21 is a top view of the piezoelectric actuator module of the third embodiment. FIG. 22 is a side view of the piezoelectric actuator module of the third embodiment. FIG. 23 is a front view of the piezoelectric actuator module of the third embodiment. In FIGS. 21 through 23, the same components as those in FIGS. 15 through 17 are denoted by the same symbols. A piezoelectric actuator module 10Y includes a casing (lid unit) 11. The topside of this casing 11 is provided with a gear 60 that functions as an output shaft to transmit drive force. Furthermore, a flexible substrate 14 provided with an external connection terminal 13 extends out from one end in the longitudinal direction of the casing 11.

The casing 11 includes a casing main body 15; a first lid unit 17-1 that is fixed to the casing main body 15 by screws 16, that protects the piezoelectric actuator main body in conjunction with the casing main body 15, and that is fixed in place to cover the portion including the rotating body and its rotation shaft, the output shaft 12; and a second lid unit 17-2 that is fixed in place to cover the piezoelectric actuator main body, part of the flexible substrate, and other portions thereof. In the present embodiment, a gear part 60A and a rotation shaft 60B that constitute the gear 60 are configured separately. Therefore, the gear part 60A can be made detachable. According to this configuration, suitable variations are possible according to the intended use. In the above descriptions, the gear part 60A and rotation shaft 60B constituting the gear 60 were configured separately, but they can also be configured integrally.

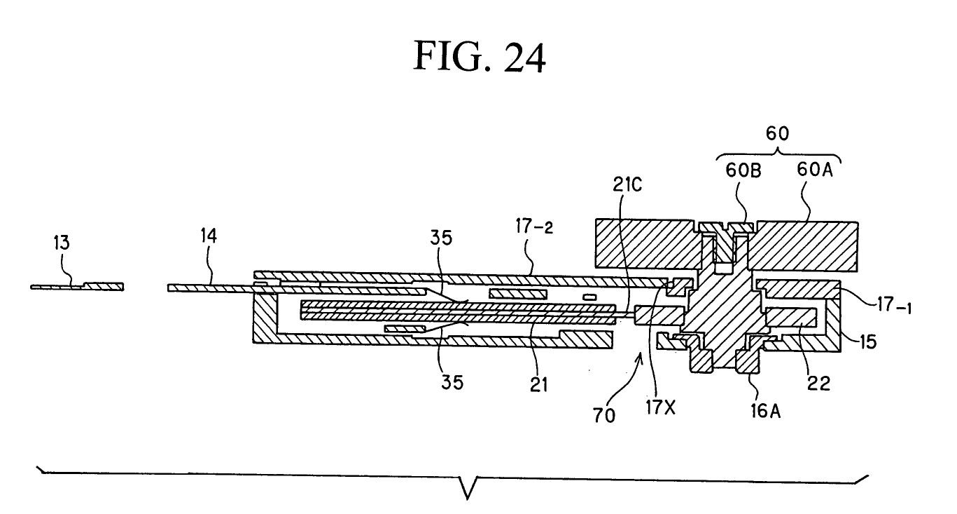

FIG. 24 is a side view along a cross section A-A in the piezoelectric actuator module 10Y. In FIG. 24, the same components as those in FIG. 2 or FIG. 17 are denoted by the same symbols. The piezoelectric actuator module 10Y is provided with an observation hole 70 that is formed in the back surface of the casing main body 15, can be blocked with a blocking plate (not illustrated), and is designed to make it possible to observe the state of contact between the contact portion 21 C of the piezoelectric actuator main body 21 and the rotating body 11.

As a result, the state of contact between the contact portion 21C and the rotating body 1 1 can be observed during manufacture of the piezoelectric actuator module 10Y, the appropriate adjustments can be made, and the results are easier to inspect. In the above descriptions, the observation hole 70 is blocked by a blocking plate (not shown), but it is possible to obtain the same results by providing a transparent member instead of the observation hole 70 and making the state of contact between the contact portion 21C and the rotating body 11 visible.

### [4.1] Modification

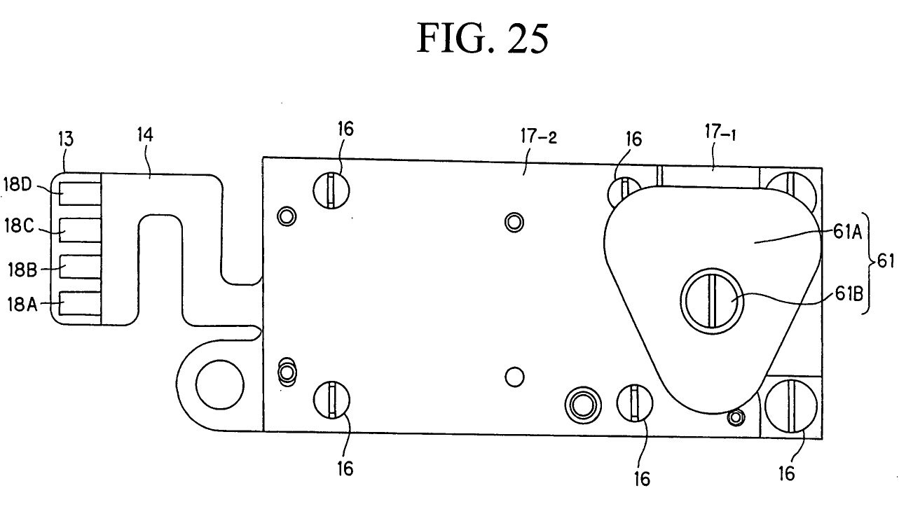

FIG. 25 is a diagram for describing the modification of the third embodiment. In FIG. 25, the same components as in FIG. 24 are denoted by the same symbols. The difference between the third embodiment and the modification of the third embodiment is that a cam 61 is provided instead of the gear 60 that functions as an output shaft. In this case, a cam part 61A and a rotation shaft 61B constituting the cam 61 are configured separately. Therefore, the cam part 61A can be made detachable. According to this configuration, suitable variations can be made according to the intended use. In the above description, the cam part 61A and rotation shaft 61B constituting the cam 61 were configured separately, but they can also be configured integrally.

### [5] Fourth Embodiment

In the third embodiment described above, the gear part of the gear or the cam part of the cam functioning as the output shaft was configured to be entirely exposed on the casing exterior, but the fourth embodiment is one in which only a part thereof is exposed.

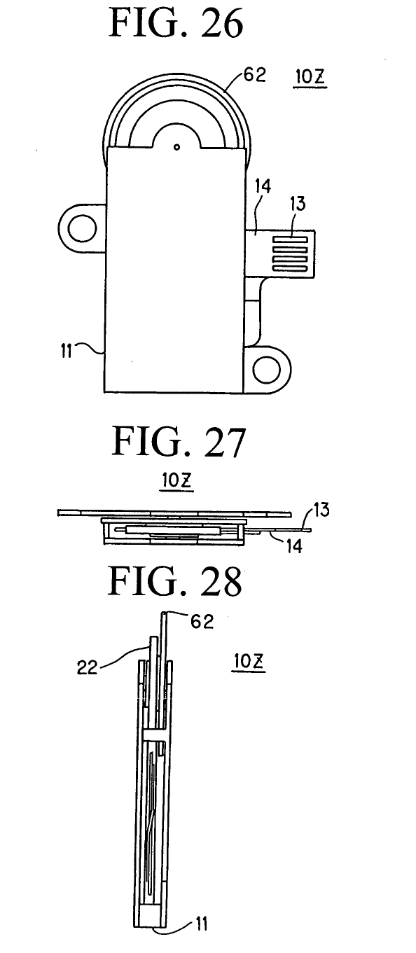

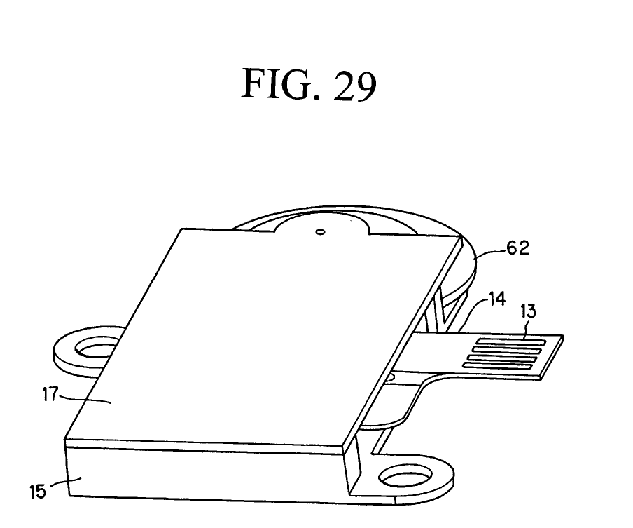

FIG. 26 is a top view of the piezoelectric actuator module of the fourth embodiment. FIG. 27 is a side view of the piezoelectric actuator module of the fourth embodiment. FIG. 28 is a front view of the piezoelectric actuator module of the fourth embodiment. FIG. 29 is an external perspective view of the piezoelectric actuator module of the fourth embodiment. In FIGS. 26 through 29, the same components as in FIGS. 21 through 23 are denoted by the same symbols.

A piezoelectric actuator module 10Z includes a casing (lid unit) 11, and part of a gear 62 that functions as an output shaft to transmit drive force protrudes from the longitudinal end of the casing 11. Furthermore, a flexible substrate 14 provided with an external connection terminal 13 extends out from one end in the longitudinal direction of the casing 11. Employing such a configuration wherein part of the gear 62 that functions as an output shaft to transmit drive force protrudes from the longitudinal end of the casing 11 makes it possible to configure a thinner piezoelectric actuator module than in the third embodiment.

### [6] Fifth Embodiment

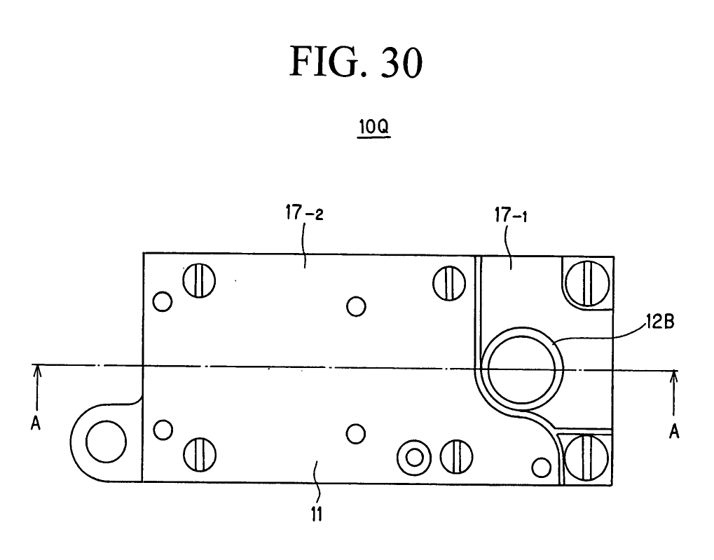

The fifth embodiment is one in which a cylindrical rotating body is used as the output shaft. FIG. 30 is an external perspective view of the piezoelectric actuator module of the fifth embodiment. A piezoelectric actuator module 10Q includes a casing (lid unit) 11. A cylindrical rotating body 12B that functions as an output shaft to transmit drive force is accommodated in the casing 11. Furthermore, an external connection terminal (for surface mounting; not shown) is provided on the rear surface of the casing 11.

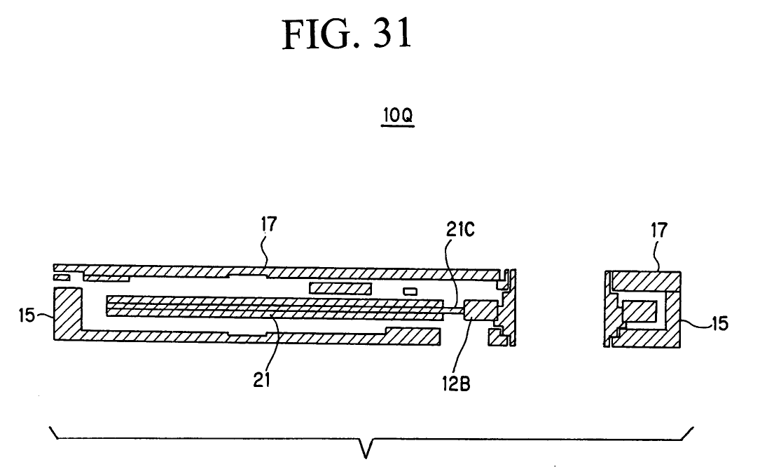

FIG. 31 is a side view along a cross section A-A of the piezoelectric actuator module of the fifth embodiment. The piezoelectric actuator main body 21 is provided on the inside of the casing main body 15. The piezoelectric actuator main body 21 is supported by a slider (not shown). The interior of the casing main body 15 is provided with a cylindrical rotating body 12B as a driven body that functions as an output shaft and is driven by the piezoelectric actuator main body 21.

As a result, light can pass through the output shaft portion, making the piezoelectric actuator module suitable for applications such as performing control while transmitting light.

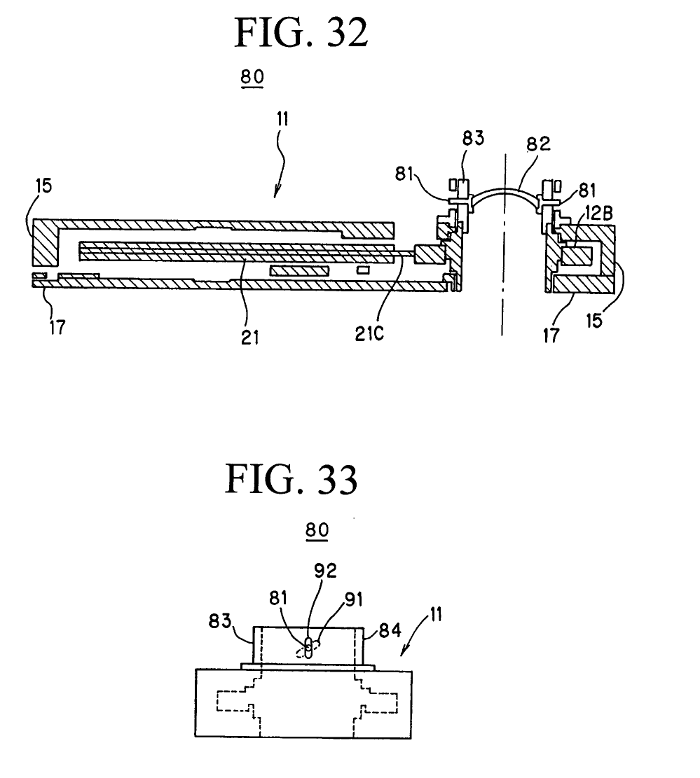

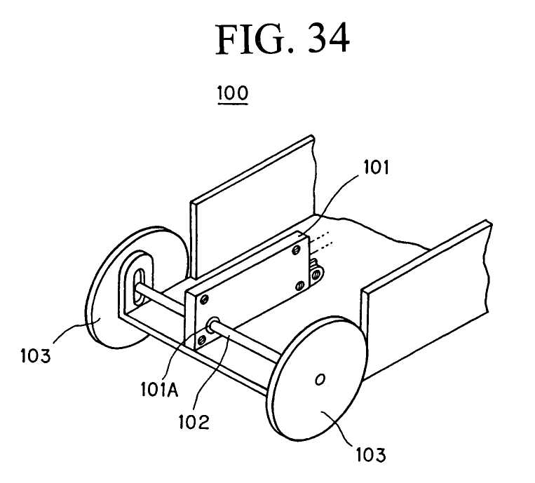

FIGS. 32 and 33 show a more detailed application example of the fifth embodiment. FIG. 32 is a cross-sectional view of a specific application example in which a lens is mounted in the hole of the output shaft portion, and the piezoelectric actuator module is used to focus the lens. FIG. 33 is a side view of a specific example of applying the piezoelectric actuator module in FIG. 32.

A focusing device 80, which is the device of the present application example, includes a lens 82 having a sliding axle 81, an internal body tube 83 rotated in conjunction with the cylindrical rotating body 12B as a result of the cylindrical rotating body 12B being rotated by the piezoelectric actuator main body 21, and an external body tube 84 fixed to the casing 11. In this case, a first guide groove 91 that extends at a slant is provided to the internal body tube 83, and a second guide groove 92 that extends vertically is provided to the external body tube 84. The first guide groove 91 and second guide groove 92 are provided so as to intersect with each other.

The operation will now be described. The internal body tube 83 rotates due to the cylindrical rotating body 12B being rotatably driven by the piezoelectric actuator main body 21. At this time, the external body tube 84 does not rotate because it is fixed to the casing 11.

Therefore, the sliding axle 81 of the lens 82 slides both along the first guide groove 91 and along the second guide groove 92. For example, in the case such as is shown in FIG. 33, the lens 82 moves downward when the internal body tube 83 turns counterclockwise as seen from above. Similarly, when the internal body tube 83 turns clockwise as seen from above, the lens 82 moves upward as a result. Thus, it is possible to move the lens 84 to the desired position. In the above description, one of possible applications was described, but it is also possible to use the present embodiment in the zoom mechanism of a compact camera or the auto-focus mechanism or the like, including compact digital cameras.

### [7] Sixth Embodiment

FIG. 34 shows the main part of an embodiment wherein the actuator module of the embodiments described above is applied to a vehicle (moving body) provided with a wheel device commonly used in toys and the like. A wheel device 100 includes an actuator module 101 as shown in FIG. 34. An axle 102 is directly connected to an output shaft 101A of the actuator module 101, and the actuator module 101 rotatably drives the axle 102, which makes it possible to drive the wheels 103 and to move the model automobile or other such vehicle for which the wheel device 100 is provided.

In the present embodiment, the suspension device is not shown, but mounting the actuator module 101, the axle 102, and the wheels 103 on the suspension device can yield a configuration in which the effects of irregularities or the like in the traveled surface can be reduced and the vehicle can run in a satisfactory manner. Also, since the actuator module can be configured to be thin and compact, batteries and other such large components can be easily arranged in a compact model automobile or the like, even in a configuration in which an actuator module is provided separately to each wheel. In the above description, the actuator module 101 directly drives the wheels 103 via the axle 102, but it is also possible to use a configuration wherein the wheels are driven via a specific deceleration gear train or acceleration gear train.

### [8] Seventh Embodiment

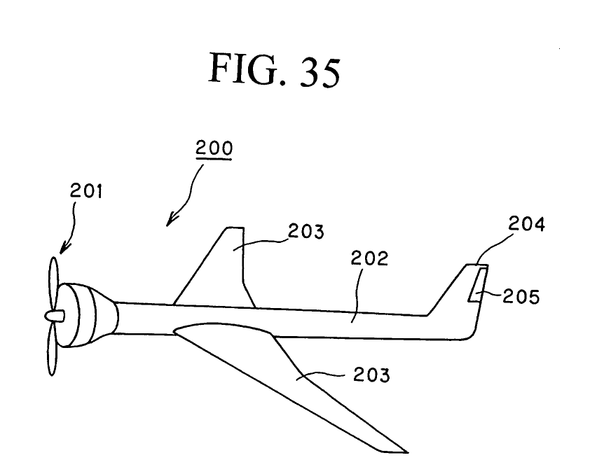

FIG. 35 is an external perspective view of a case in which the actuator module of the embodiments described above is applied to a model airplane (aircraft). A model airplane 200 includes a propeller device 201 and is made to fly due to the propulsive force generated by the propeller device 201. The model airplane 200 also includes main wings 203 extending to the left and right from the vehicle main body 202, and a tail fin 204 provided to the back part of the vehicle main body 202. The tail fin 204 is provided with a rudder 205, and it is possible to adjust the direction in which the model airplane 200 travels by driving the rudder 205.

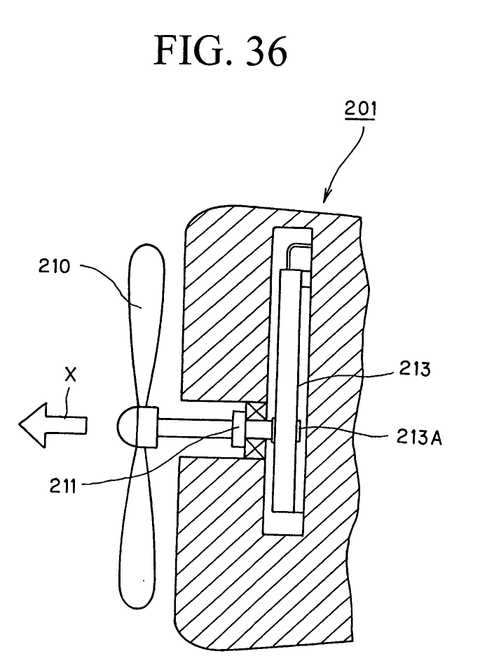

The details of the propeller device 201 will now be described. FIG. 36 is a partial cross-sectional view of the propeller device. The propeller device 201 has an axle 211 that is rotatably supported and integrated with a propeller 210 on the vehicle main body (supporting body) 202.

The axle 211 is integrated with an output shaft 213A of an actuator module 213, and when the output shaft 213A of the actuator module 213 is rotatably driven, propulsive force is generated in the direction of the arrow X in the diagram by the resulting rotation of the propeller 210, and the model airplane 200 is caused to fly. As described above, according to the present embodiment, it is easy to make the actuator module compact and lightweight, so the actuator module can be reduced in weight and it is possible to fly a larger model airplane over a longer period of time compared to a model airplane in which a coil motor is installed. In the above description, the actuator module 213 directly drives the propeller 210, but it is also possible to use a configuration wherein the propeller is driven via a specific deceleration gear train or acceleration gear train.

### [9] Eighth Embodiment

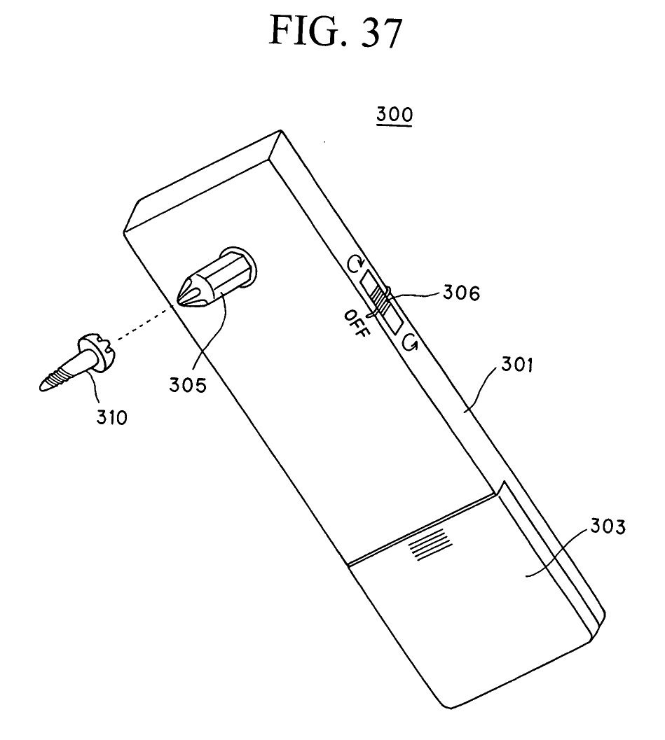

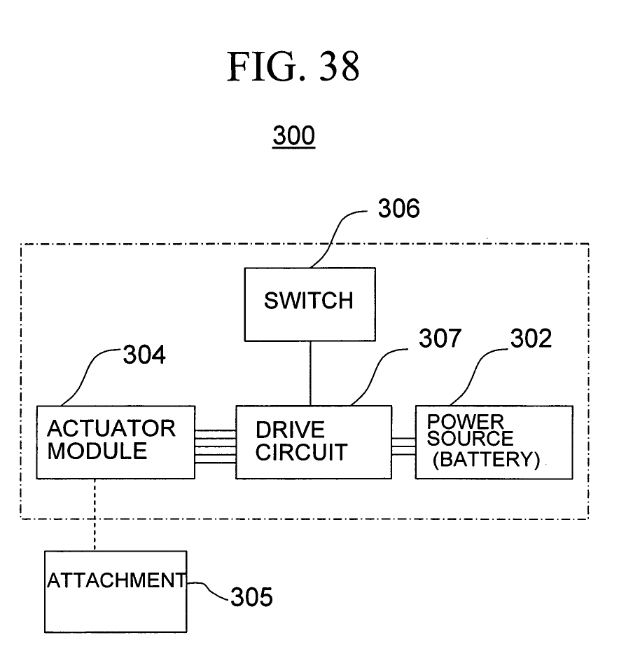

FIG. 37 is an external perspective view of an electric tool of the ninth embodiment. FIG. 38 is a schematic structural block view of an electric tool of the ninth embodiment. An electrical tool 300 includes a casing 301, a lid unit 303 constituting the casing 301 and accommodating a battery 302 as a fuel source in its interior, an actuator module 304, an attachment (the cross-shaped driver pin in FIG. 36) 305 detachably affixed to the output shaft of the actuator module 304 installed in the casing 301, an operating switch 306 to switch the direction of rotation and changing the stops, and a drive circuit 307 mounted in the casing 301 and used to drive the actuator module 304 by the supply of power from the battery 302 in accordance with the operating state of the operating switch 306.

According to the configuration described above, the output shaft of the actuator module 304, and hence the attachment 305 affixed to the output shaft, are rotatably driven by the drive circuit 307 according to user's operation of the operating switch 306 to attach or to remove a screw 310. In this case, the actuator module 304 can yield a greater torque than a coil motor of the same volume, and it is possible to configure a compact electrical tool with a wide range of applications. As described above, according to the present embodiment, the actuator module can be used to configure a compact electrical tool with a high torque.

### [10] Ninth Embodiment

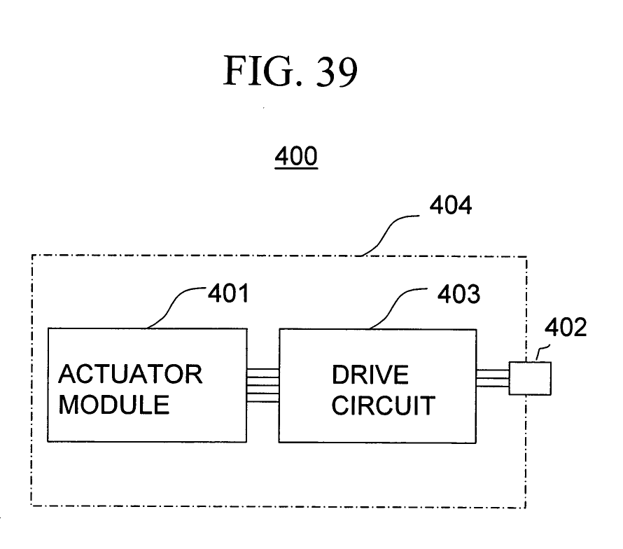

FIG. 39 is a schematic structural block diagram of the electric motor module of the tenth embodiment. An electric motor module 400 includes an actuator module 401, a drive circuit 403 to drive the actuator module 401 due to a supply of power from the exterior via a power source supply terminal 402, and a casing 404 to accommodate the actuator module 401 and the drive circuit 403, wherein the power source supply terminal 402 is exposed to the exterior. According to the ninth embodiment, the output shaft (not shown) of the actuator module 401 can be rotated merely by connecting an external power source to the power source supply terminal 402, and the electric motor module can be handled in the same manner as a regular coil motor.

### [11] Tenth Embodiment

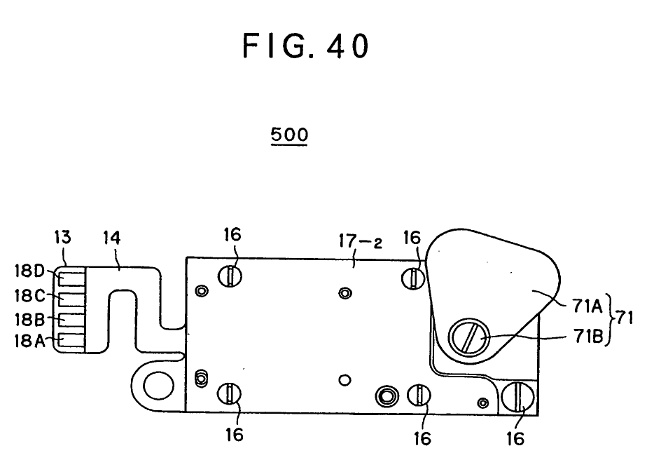

FIG. 40 is an external front view of the oscillating electric motor module of the tenth embodiment. In FIG. 40, the same components as those in the modification of the third embodiment in FIG. 25 are denoted by the same symbols. The tenth embodiment is comparable to the third embodiment, and is configured as an oscillating electric motor module 500 to handle incoming information in a portable phone, wherein an eccentric counterweight 71 is provided instead of the gear 60 that functions as an output shaft. In this case, a counterweight part 71A and an axle 71B constituting the eccentric counterweight 71 are configured separately. Because of the need to maintain high oscillation, metal material with a high specific gravity, for example, tungsten, is used as the counterweight part 71A. In this case, the counterweight part 71A can be made detachable and can be varied according to the required oscillation or the like.

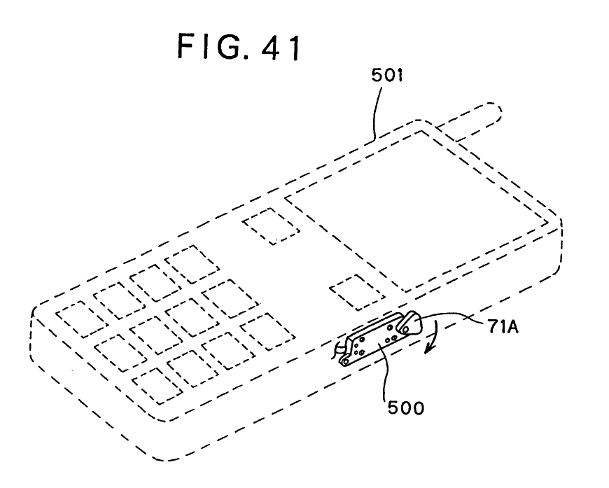

FIG. 41 is an explanatory diagram of a state in which the oscillating electric motor module 500 is incorporated into a portable phone 501. The oscillating electric motor module 500 can be formed to be extremely small as shown in FIG. 41, and there is enough space to hold the module even in a compact portable phone 501. When the portable phone 501 receives a signal, the counterweight part 71A rotates in the direction of the arrow in FIG. 41, for example, and the phone oscillates due to a counterweight imbalance in the axle 71B of the counterweight part 71A, whereby the user can be informed of the incoming signal by the oscillation.

### [12] Eleventh Embodiment

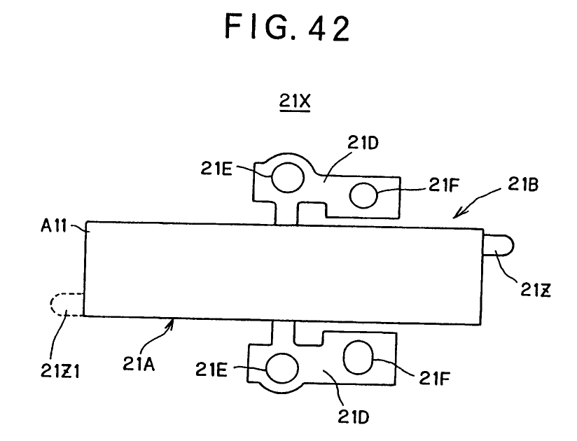

FIG. 42 is a top view of the piezoelectric actuator main body (oscillator) of the eleventh embodiment. A piezoelectric actuator main body 21X has a structure wherein PZT or other such piezoelectric elements 21B are affixed to both sides of a substrate (shim) 21A, which is an elastic member. In this structure, during actual driving, for example, a voltage V− (negative voltage) is applied to the substrate 21A, and a voltage V+ (positive voltage) is applied to the piezoelectric elements 21B.

Fixing units 21D to fix the piezoelectric actuator main body 21 to the slider 23 are provided on both sides of the substrate 21 A, and the main body is supported by the sections to which the piezoelectric elements 21B are affixed in a suspended state. These fixing units 21D are each provided with a positioning hole 21F and a screw hole 21E through which a screw is inserted to fix the main body to the slider 23. The piezoelectric elements 21B are provided with a single region A11 wherein a drive signal is applied.

More specifically, the piezoelectric actuator main body 21X is driven by applying a drive voltage to the region A11. Longitudinal oscillation is then induced, but since the contact portion 21Z is provided to a position asymmetrical to the substrate 21A, an imbalance occurs in the longitudinal expansion and contraction, curved oscillation is induced, and oscillation is created along an elliptical orbit in a constant direction in relation to the contact portion 21Z (for example, in a clockwise direction). Specifically, the piezoelectric actuator main body 21X of the present embodiment makes it possible to configure a piezoelectric actuator capable of rotating in one direction merely by providing one electrode. In order to make oscillation more reliable, a balancing part 21Z1 with the same shape as the contact portion 21Z may be provided at a position that is substantially asymmetrical to the position at which the contact portion 21Z is provided in relation to the center of the rectangular substrate.

### [13] Twelfth Embodiment

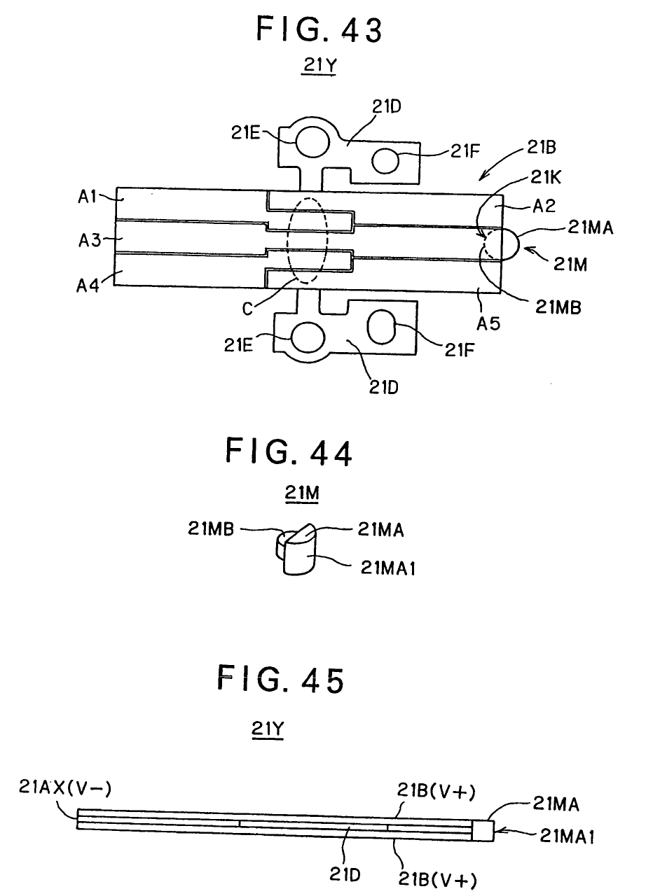

FIG. 43 is a top view of the piezoelectric actuator main body (oscillator) of the twelfth embodiment. FIG. 44 is an external perspective view of the contact portion. FIG. 45 is a side view of the piezoelectric actuator main body (oscillator) of the twelfth embodiment. The substrate 21A is formed, for example, from SUS301EH with a Vickers hardness of 500 HV and a Young's modulus of 210 GPa.

The contact portion 21M, however, is configured from alumina with a Vickers hardness of 1600 HV and a Young's modulus of 350 to 380 GPa, and includes a contact end part 21MA having a contact surface 21MA1 that is pressed against the rotating body, and a fixed part 21MB that is fixed in place and supported in a concavity 21K provided to one end of the substrate in order to support the contact end part 21MA. The contact end part 21MA is formed into a half cylinder as shown in FIG. 44, for example, and has a thickness commensurate with the thickness obtained by adding the piezoelectric elements 21B (two layers) to the thickness of the substrate 21A, as shown in FIG. 45.

Also, the fixed part 21MB is formed into a half cylinder with the same shape as the concavity 21K provided on one end of the substrate 21 A, and the thickness thereof is commensurate with that of the substrate 21A. The fixed part 21MB is in a state of being fixed to the substrate 21A and held from both sides by the two piezoelectric elements 21 B. The piezoelectric elements 21B, the substrate 21A, and the contact portion 21M are bonded and fixed to each other with a cured epoxy resin adhesive at room temperature. Because of the configuration described above, the substrate 21A and the contact portion 21M can be configured from materials suitable for their respective functions.

As described above, the substrate 21A is configured from SUS301EH, and it compensates for the brittleness of the piezoelectric elements 21B while not impeding the oscillation of the piezoelectric elements 21B. Also, since the contact portion 21M is configured from alumina, the abrasion resistance of the contact surface 21MA1 in contact with the rotating body can be improved, so the durability of the piezoelectric actuator module is also improved.

### [14] Thirteenth Embodiment

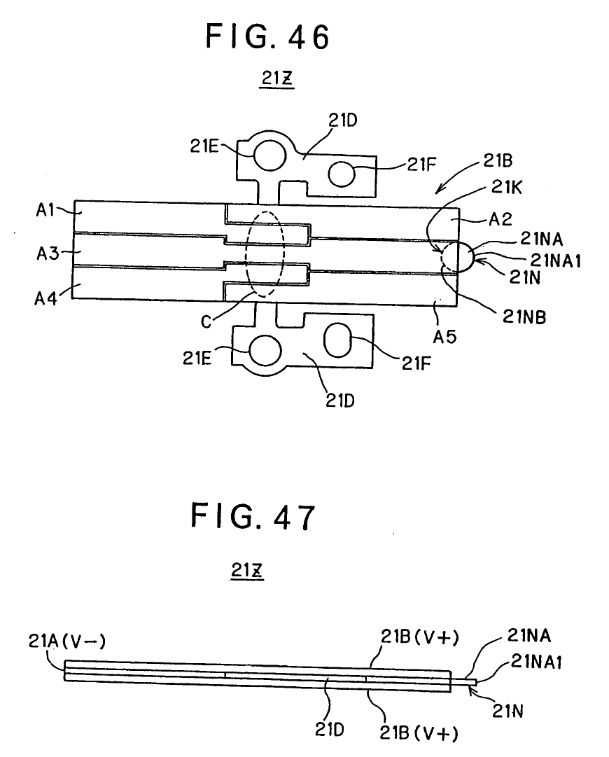

FIG. 46 is a top view of the piezoelectric actuator main body (oscillator) of the thirteenth embodiment. FIG. 47 is a side view of the piezoelectric actuator main body (oscillator) of the thirteenth embodiment. The substrate 21A constituting the piezoelectric actuator main body 21Z if formed, for example, from SUS301EH with a Vickers hardness of 500 HV and a Young's modulus of 210 GPa.

The contact portion 21N, however, is configured from strong steel alloy H1 (WC particle diameter 1 μm, Co content 10%) with a Vickers hardness of 1500 HV and a Young's modulus of 700 GPa, and includes a contact end part 21NA having a contact surface 21NA1 that is pressed against the rotating body, and a fixed part 21NB that is fixed in place and supported in a concavity 21K provided to one end of the substrate 21A to support the contact end part 21NA. The entire contact portion 21N is formed into a disc shape.

The contact portion 21N is made, for example, by cutting a rod of cemented carbide H1 down to an appropriate thickness and grinding the rod in the thickness direction to remove burrs resulting from cutting. The portion is formed such that a cross sectional shape in which the contact surface 21NA1 is cut in the direction parallel to the paper surface in FIG. 47 forms an arc-shaped convexity in relation to the rotating body.

Also, the fixed part 21NB is formed into a half cylinder with the same shape as the concavity 21K provided on one end of the substrate 21A, and the thickness thereof is commensurate with the substrate 21A. The fixed part 21NB is fixed to the substrate 21A and is sandwiched between the two piezoelectric elements 21B; and the piezoelectric elements 21B, the substrate 21A, and the contact portion 21N are bonded and fixed to each other with a cured epoxy resin adhesive at room temperature. Because of the configuration described above, the substrate 21A and the contact portion 21N can be configured from materials suitable for their respective functions.

As described above, the substrate 21A is configured from SUS301EH, and it compensates for the brittleness of the piezoelectric elements 21B while not impeding the oscillation of the piezoelectric elements 21B. Also, since the contact portion 21N is configured from cemented carbide H1, the abrasion resistance of the contact end surface 21NA1 in contact with the rotating body can be improved, so the durability of the piezoelectric actuator module is also improved.

### [15] Modifications of the Embodiments

In the above description, SUS301EH was used as the material for the substrate 21A, but the material is not limited thereto and other types of stainless steel may also be used. Alternatively, the substrate may be configured from aluminum, amorphous metal, rubber metal, or another such material that has a low Young's modulus, oscillates readily, and does not impede the oscillation of the piezoelectric elements 21B.

In the above description, alumina or cemented carbide was used as the material for the contact portion provided separately from the substrate 21A, but the material is not limited to these options alone and may be silicon nitride, zirconia, silicon carbide, or another type of ceramic; or nitrided steel, cemented steel, or another type of treated steel. In other words, the material for the contact portion should be selected such that at least the surface in contact with the rotating body has a higher degree of hardness than the substrate material in cases in which the contact portion can be configured from the substrate 21A alone.

In the above description, the substrate and piezoelectric elements were substantially rectangular and plate-shaped, but other shapes may be arbitrarily selected according to the application conditions and intended use. For example, in the above description, the piezoelectric elements were formed into substantially flat surfaces, but it is also possible to use a block configuration or the like. In these cases, the contact portion should be formed so as to protrude in a specific direction from the end of the piezoelectric elements on the side of the rotating body. The specific direction is within ±30° of the surface perpendicular to the plane that contains the end surface of the piezoelectric elements on the side of the rotating body, and is more preferably within ±15°, and even more preferably within ±10°.

1. A piezoelectric actuator module comprising:
a piezoelectric actuator main body having electrodes;
a signal input terminal for inputting a drive signal from the exterior and supplying said drive signal to said electrodes;
a rotating body being disposed in substantially the same plane as said piezoelectric actuator main body to be in contact with a part of said piezoelectric actuator main body and being rotatably driven by said piezoelectric actuator main body;
a casing accommodating said piezoelectric actuator main body electrically connected to said rotating body and a signal input terminal; and
an output shaft being exposed from said casing and by which the rotational movement transmitted directly or indirectly by said rotating body is outputted to the exterior.

2. The piezoelectric actuator module according to claim 1, further comprising,
a slider to support said piezoelectric actuator main body,
wherein said piezoelectric actuator main body is pressed against said rotating body by rotating or translating said slider.

3. The piezoelectric actuator module according to claim 2, comprising an urging member to urge said slider toward said rotating body.

4. The piezoelectric actuator module according to claim 3, wherein said urging member is configured to be replaceable.

5. The piezoelectric actuator module according to claim 3, comprising an urging force varying part to vary an urging force applied to said slider by said urging member.

6. The piezoelectric actuator module according to claim 1, wherein
said casing comprises a lid unit and a casing main body,
said lid comprises a first lid unit to cover portions corresponding to said rotating body and said output shaft, and
a second lid unit to cover a portion corresponding to said piezoelectric actuator main body.

7. The piezoelectric actuator module according to claim 6, wherein said first lid unit and said second lid unit can be assembled in a partially overlapped state.

8. The piezoelectric actuator module according to claim 1, wherein an observation window or transparent member that allows a contact state to be observed from the exterior of said casing is provided on said casing.

9. The piezoelectric actuator module according to claim 1, wherein
said rotating body has an axle; and
a bearing part supporting said axle is extended from a peripheral surface of said casing.

10. The piezoelectric actuator module according to claim 1, wherein said output shaft is connected to said rotating body, and a drive force transmission part is connected via said output shaft.

11. The piezoelectric actuator module according to claim 10, wherein said drive force transmission part has a gear or a cam, and said gear or cam is either fixed or detachably disposed.

12. The piezoelectric actuator module according to claim 1, wherein said output shaft has a substantially cylindrical shape.

13. The piezoelectric actuator module according to claim 1, wherein a ground electric potential of a driving power source of said piezoelectric actuator main body is the same as an electric potential of said casing.

14. The piezoelectric actuator module according to claim 1, wherein
said piezoelectric actuator main body comprises a substrate in which piezoelectric elements are layered over a plurality of regions on a surface thereof, a fixing part to fix said substrate to a slider, and a contact portion provided on a longitudinal end of said substrate,
said piezoelectric elements are stretched and contracted by supplying a drive signal to said piezoelectric elements to create longitudinal oscillation whereby said oscillating plate expands and contracts in the longitudinal direction, and to create curved oscillation in a direction intersecting with said longitudinal direction, and said rotating body is rotatably driven by displacement of said contact portion that accompanies a combined oscillation obtained by combining said oscillations.

15. The piezoelectric actuator module according to claim 1, comprising,
a supporting slider to press said piezoelectric actuator main body against said rotating body, and
a flexible substrate designed to supply driving electric power to said piezoelectric actuator main body from an external connecting terminal and electrically connected to said electrodes of the piezoelectric actuator main body, wherein
said flexible substrate comprises a casing support part supported by said casing, a slider support part supported by said slider, and a damper part disposed in a middle portion between said casing support part and said slider support part and designed to reduce stress or to suppress oscillation transmission between said two support parts.

16. The piezoelectric actuator module according to claim 1, wherein
said piezoelectric actuator main body comprises a substrate in which piezoelectric elements are layered on a surface thereof, and
a contact portion that is configured separately from said substrate, supported by said substrate, and pressed against said rotating body, and
at least the portion of said contact portion pressed against said rotating body is configured with a higher degree of hardness than that of said substrate.

17. The piezoelectric actuator module according to claim 16, wherein one end of said contact portion protrudes from an end surface of said substrate in a specific direction, and an opposite end is fixed in place and supported in a concavity provided in said opposite end of said substrate.

18. The piezoelectric actuator module according to claim 16, wherein said contact portion is configured from ceramics, cemented carbide, nitrided steel, or cemented steel.

19. The piezoelectric actuator module according to claim 1, wherein a plurality of electrodes and signal input terminals are provided.

20. An electric motor module, comprising:
a piezoelectric actuator main body having electrodes;
signal input terminals to input a drive signal and supplying said drive signal to said electrodes;
a rotating body being disposed in substantially the same plane as said piezoelectric actuator main body to be in contact with a part of said piezoelectric actuator main body and being rotatably driven by said piezoelectric actuator main body;
a casing accommodating said piezoelectric actuator main body electrically connected to said rotating body and the signal input terminals;
an output shaft being exposed from said casing and rotational movement transmitted directly or indirectly by said rotating body is outputted to the exterior; and
a drive circuit creating said drive signal on the basis of electric power supplied from the exterior and outputting said signal to said signal input terminal.

21. An apparatus comprising:
a piezoelectric actuator main body having electrodes;
a plurality of signal input terminals inputting a drive signal and supplying said drive signal to said electrodes;
a rotating body being disposed in substantially said same plane as the piezoelectric actuator main body to be in contact with a part of said piezoelectric actuator main body and being rotatably driven by said piezoelectric actuator main body;
a casing accommodating said piezoelectric actuator main body electrically connected to said rotating body and said signal input terminals;
an output shaft being exposed from said casing and by which rotational movement transmitted directly or indirectly by said rotating body is outputted to the exterior;
a driven part being connected to and driven by said output shaft;
a power source supplying electric power; and
a drive circuit creating said drive signal on the basis of said electric power supplied from said power source and outputting said signal to said signal input terminals.

22. The apparatus according to claim 21, wherein said driven body is a gear, a propeller, or a tool attachment.
